(19) United States
(12) Patent Application Publication
(10) Pub. No.: US 2012/0070590 A1
(43) Pub. Date: Mar. 22, 2012

(54) PLASMA ENHANCED ATOMIC LAYER DEPOSITION APPARATUS AND THE CONTROLLING METHOD THEREOF

(75) Inventors: Jen-Rong Huang, Hsinchu City (TW); Tean-Mu Shen, Hsinchu City (TW); Kang-Feng Lee, Taipei City (TW); Chin-Chong Chiang, Hsinchu County (TW); Sheng-Lang Lee, Hsinchu County (TW); Jung-Chen Ho, Hsinchu City (TW); Ching-Chiun Wang, Miaoli County (TW)

(73) Assignee: Industrial Technology Research Institute, Hsinchu (TW)

(21) Appl. No.: 12/970,403

(22) Filed: Dec. 16, 2010

(30) Foreign Application Priority Data
Sep. 16, 2010 (TW) 099131387

(51) Int. Cl. C23C 16/448; C23C 16/02

(52) U.S. Cl. 427/532; 118/719

(57) ABSTRACT

This prevent disclosure provides a plasma enhanced atomic layer deposition apparatus and the controlling method thereof. The plasma enhanced atomic layer deposition apparatus includes: a plurality of reaction chambers, each of the reaction chambers having a first reaction space and a second reaction space; an adjustable partition unit controlled to separate or communicate the first and the second reaction spaces; and a plurality of heating carriers respectively disposed in the plurality of reaction chambers. The method manipulates the movement of the partition plate, leading to separation or communication between the first and second reaction spaces, so as to avoid the interference or inter-reaction between process gases and the resultant particles contaminating the substrates.

### TECHNICAL FIELD

The present disclosure relates to a film deposition apparatus, and more particularly, to a plasma enhanced atomic layer deposition apparatus and the controlling method thereof.

### TECHNICAL BACKGROUND

As the development and advances of the semiconductor manufacturing technology, the ratio of depth to width, a key structural parameter to fabricate nano-scale devices, has been upgraded remarkably. The atomic layer deposition (ALD) process, being one of the major advances, has been increasingly applied to a variety of fields of production. In order to soar the speed of processing the conventional thermal-mode ALD and to form films of particular requirements, the plasma enhanced atomic layer deposition (PEALD) process has been introduced and developed recently. Basically, the PEALD process is combined by both the ALD and the plasma enhanced chemical vapor deposition (PECVD) processes. Although the PEALD process has a more extensional range of applications than the ALD, it suffers from plasma damage and interference of the precursor gases, which lead to the formation of particles and thus contamination on the substrates or in the reaction chambers.

The quality of deposited films and the mass-production capacity are of great importance for current semiconductor foundries. Due to superior improvement of the ALD deposition film quality to the other techniques, the vendors of equipment have put their major efforts on becoming more capable of reliable mass production of the ALD. However, in the mean time, the main challenges of the ALD fall on how to rapidly attach uniform saturated precursor gases onto the substrates and to completely clear the residue of the precursor gases and diminish the side effects of reaction, both of which are concerned with the layout of structure of the ALD apparatus. According to the recent tendency of the ALD structural layout in whether the claims of the filed patents or the commercial equipments, most of the ALD reaction chambers of thermal batch may be provided with precursor gases of disturbance in all time; wherein concentrations of the precursors can be decreased in order to increase the duration of their chemical attachment on the substrates and to enhance the efficiency of reaction. Most of the conventional reaction chambers for the single-wafer ALD process are designed as the scheme of compression and arc-shaping to decrease the usage of precursor gases and increase the efficiency of gas supply. Comparing to the thermal-mode ALD, the PEALD process has more advantageous merits, such as low-temperature process, excellent adjustability of interface of the substrates and oxides, good attachment onto the plastic substrate surface, low-stress film formation, and high selectivity of precursor. It is believed that the PEALD would be one of the essential processes in the fabrication of the flexible electro-optical devices.

In the US Pat. Pub. No. 2007/0128864, a PEALD apparatus is disclosed that a showerhead is configured below a plasma baffle and a plasma screen to direct process gases to the area for plasma ionization, which then flow onto a substrate by the passage in the plasma baffle. On the other hand, another process gas is introduced through a hole in the upper part of the showerhead onto the substrate. The U.S. Pat. No. 6,820,570 describes a PEALD apparatus that includes a two-piece showerhead. Movement of one of the pieces can control the opening size of the showerhead and then the flow rate and distribution of the process gases. The reaction chamber therein is divided by a divider plate into two sections: the lower one is for a precursor gas and the upper one for another precursor. The plasma is de-ionized and then introduced onto the substrates through the showerhead. Also in the U.S. Pat. No. 7,153,542 and the US Pat. Pub. No. 2008/0075858, there proposed a PEALD apparatus having multiple reaction chambers for various processes respectively. A mobile pedestal is used to carry several substrates, which are shifted in sequence to be processed in each individual reaction chambers.

### TECHNICAL SUMMARY

The present disclosure provides a plasma enhanced atomic layer deposition apparatus and the controlling method thereof. The PEALD apparatus includes a mobile partition device to switch its partition plate to separate two reaction spaces in a reaction chamber, such that substrates can be transported between the two reaction spaces to be respectively reacted with gas precursors; thus, the possibility of mixture of different gas precursors can be minimized. The PEALD apparatus has multiple reaction chambers to allow the process applied to various substrates concurrently. By appropriately scheduling two processes in different reaction chambers, films can be deposited on various substrates; therefore, the throughput can be increased. Moreover, the reaction chambers of the PEALD apparatus may share the equipments of gas supplying, gas pumping, and system controlling to decrease the cost of production and equipment.

The present disclosure provides a plasma enhanced atomic layer deposition apparatus with a remote plasma source, whereby the remote de-ionization of plasma from a substrate or a wafer may diminish the effects of energy decay and recovery of the de-ionized active substances. Moreover, each precursor (or process gas) is brought into each reaction chamber through different gas passages, so that the precursors will not interfere or react with each other to cause particles formed in the chambers.

According to one aspect of the present disclosure, one embodiment provides a plasma enhanced atomic layer deposition apparatus including: a plurality of reaction chambers, each of the reaction chambers having a first reaction space and a second reaction space; an adjustable partition unit controlled to separate or communicate the first and the second reaction spaces; a first gas supply unit providing each of the first reaction spaces with a first process gas; a second gas supply unit providing each of the second reaction spaces with a second process gas; a purge gas supply unit providing each of the reaction chambers with a purge gas to purge the reaction chambers; and a plurality of heating carriers respectively disposed in the reaction chambers, each of the heating carriers controlled to move between the first and second reaction spaces in a reciprocating manner.

According to another aspect of the present disclosure, another embodiment provides a plasma enhanced atomic layer deposition apparatus including: a first and second reaction chambers, each of the reaction chambers having a first reaction space and a second reaction space; a partition plate alternatively switched to one of the reaction chambers and characterized by that if the partition plate is switched to the first reaction chamber, the first and the second reaction spaces thereof are separated and the first and the second reaction spaces of the second reaction chamber are communicated; or if the partition plate is switched to the second reaction chamber, the first and the second reaction spaces thereof are separated and the first and the second reaction spaces of the first reaction chamber are communicated; a first gas supply unit providing each of the first reaction spaces with a first process gas; a second gas supply unit providing each of the second reaction spaces with a second process gas; a purge gas supply unit providing each of the reaction chambers with a purge gas to purge the reaction chambers; and a pair of heating carriers respectively disposed in the reaction chambers, each of the heating carriers controlled to move between the first and second reaction spaces in a reciprocating manner.

According to still another aspect of the present disclosure, another embodiment provides a method for controlling a PEALD apparatus comprising the steps of: providing a PEALD apparatus comprising two reaction chambers and a partition unit, each of the reaction chambers having a heating carrier, a first reaction space provided with a first process gas, and a second reaction space provided with a second process gas to proceed a PEALD process, the partition unit configured to separate the first and the second reaction spaces of one of the reaction chambers while to communicate the first and the second reaction spaces of the other reaction chamber; providing each of the heating carriers with a substrate; positioning the partition unit into one of the reaction chamber to separate the first and the second reaction spaces thereof, and the other reaction chamber being a communicated one, wherein the substrate in the separated reaction chamber is located in the first reaction space thereof, while the substrate in the communicated reaction chamber is located in the second reaction space thereof; forming a thin film on each of the substrates by applying the PEALD process in the reaction chambers; moving the partition unit into the other reaction chamber, wherein the substrate in the separated reaction chamber is located in the first reaction space thereof, while the substrate in the communicated reaction chamber is located in the second reaction space thereof; repeating the foregoing steps of forming and moving for a predetermined times.

Further scope of applicability of the present application will become more apparent from the detailed description given hereinafter. However, it should be understood that the detailed description and specific examples, while indicating exemplary embodiments of the disclosure, are given by way of illustration only, since various changes and modifications within the spirit and scope of the disclosure will become apparent to those skilled in the art from this detailed description.

### BRIEF DESCRIPTION OF THE DRAWINGS

The present disclosure will become more fully understood from the detailed description given herein below and the accompanying drawings which are given by way of illustration only, and thus are not limitative of the present disclosure and wherein:

FIG. 1A is a structure diagram showing a PEALD apparatus according to the first embodiment of the present disclosure.

FIGS. 1B and 1C are schematic structures of two exemplary partition unit used in the embodiment of FIG. 1A.

FIG. 2A is a structure diagram showing another PEALD apparatus according to the second embodiment of the present disclosure.

FIGS. 2B and 2C are schematic structures of the aperture adjusters of the partition unit.

FIG. 3 is a top view schematically showing the PEALD apparatus according to the third embodiment of the present disclosure.

FIGS. 4A and 4B illustrate top views of other embodiments with four and five reactors, respectively.

FIG. 5A schematically illustrates another exemplary layout of the PEALD apparatus.

FIG. 5B is a schematic structure of the partition unit used in the embodiment.

FIGS. 6A and 6B are flowcharts schematically showing a method of controlling a PEALD apparatus according to an embodiment of the present disclosure.

FIGS. 7A and 7B are structure diagrams of possible situations of the PEALD apparatus according to the first embodiment.

### DESCRIPTION OF THE EXEMPLARY EMBODIMENTS

For further understanding and recognizing the fulfilled functions and structural characteristics of the disclosure, several exemplary embodiments cooperating with detailed description are presented as the following.

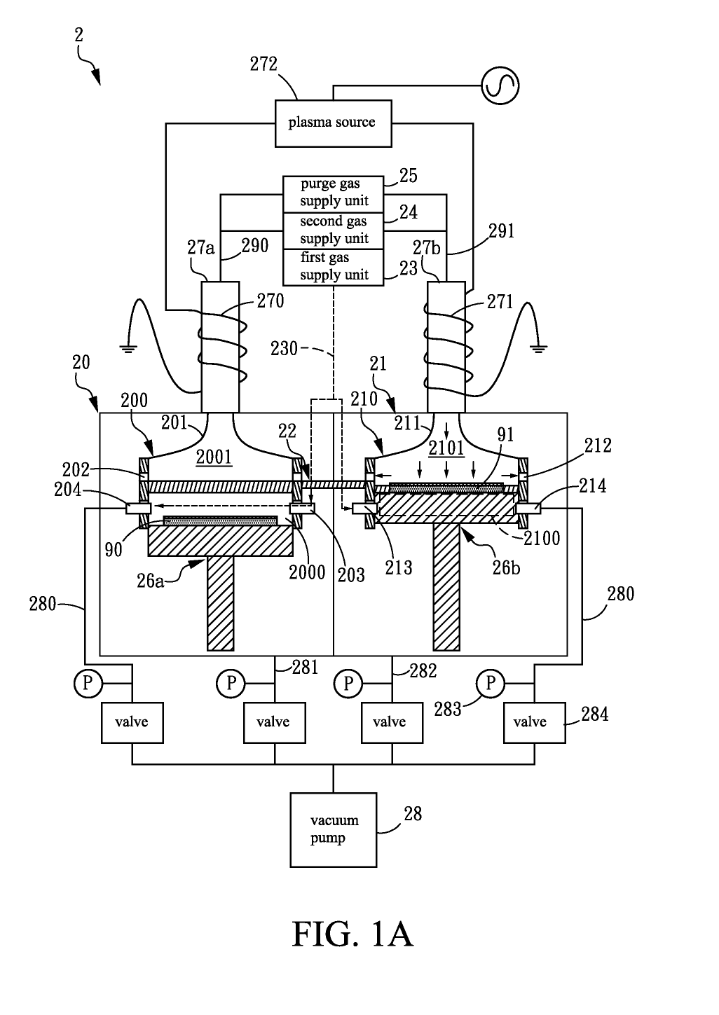

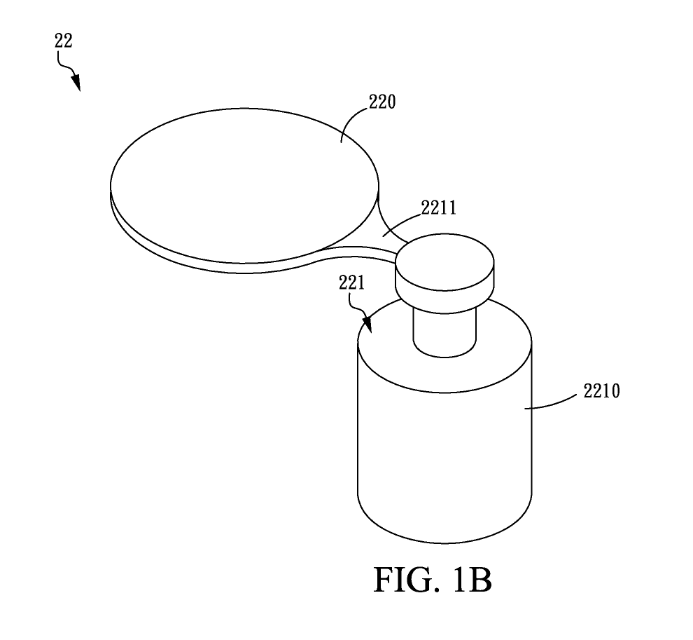

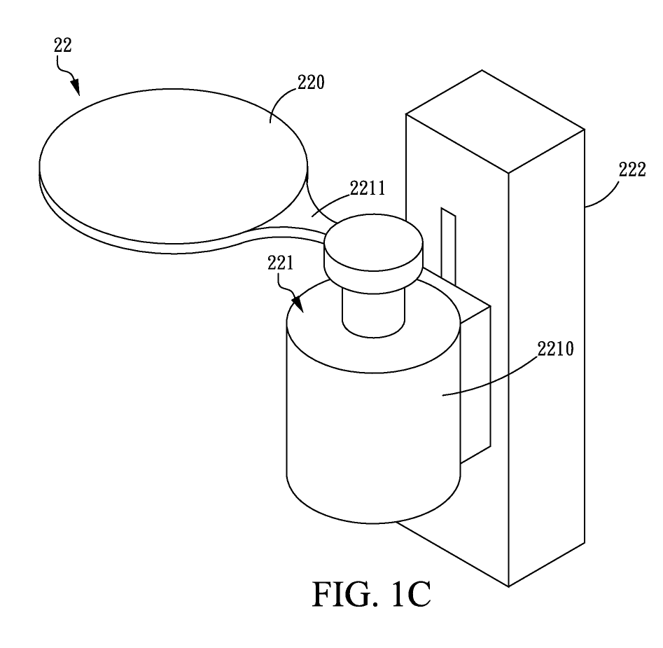

Please refer to FIG. 1A, which is a structure diagram showing a plasma enhanced atomic layer deposition (PEALD) apparatus according to the first embodiment of the present disclosure. In FIG. 1A, the PEALD apparatus 2 includes: a pair of reactors 20 and 21, an partition unit 22, a first gas supply unit 23, a second gas supply unit 24, a purge gas supply unit 25, and a pair of heating carriers 26a and 26b. The two reactors 20 and 21 are adjacently jointed, and each reactor 20 and 21 includes a reaction chamber 200 and 210. The reaction chamber 200 has a first reaction space 2000 and a second reaction space 2001, and the reaction chamber 210 has a first reaction space 2100 and a second reaction space 2101. Two extension parts 27a and 27b are respectively disposed on the reaction chambers 200 and 210, and are respectively connected to the purge gas supply unit 25 and the second gas supply unit 24. Plasma generating coils 270 and 271 that are remote plasma generators connected to the same remote plasma source 272 are respectively disposed around the extension part 27a and 27b. The remote de-ionization of plasma from a substrate or a wafer may diminish the effects of energy decay and recovery of the de-ionized active substances.

Moreover, curve structures 201 and 211 are respectively disposed between each of the reaction chambers 200 and 210 and its corresponding extension parts 27a and 27b to prevent condensation of the reaction gases, which may be cooled due to vacuum-like conditions in the reaction chambers 200 and 210. The condensation may degrade performance of the PEALD process. Openings 202 and 212 are respectively configured on the sidewall of the reaction chambers 200 and 210. Gas inlets 203 and 213 and gas outlets 204 and 214 are respectively formed on the sidewall of the first reaction spaces 2000 and 2100 below the openings 202 and 212. A gas passage 230 is disposed to connect the first gas supply unit 23 and the gas inlets 203 and 213, while another gas passage 280 is disposed to connect a vacuum pump 28 and the gas outlets 204 and 214. Also, still other gas passages 281 and 282 are respectively disposed to connect the vacuum pump 28 and the reactors 20 and 21. In this embodiment, pressure gauges 283 and air valves 284 are configured in the gas passages 280, 281, and 282 to measure and control the gas flows therein.

A partition unit 22 is used to manipulate the separation or communication of the first and the second reaction spaces in the reactors 20 and 21. As shown in FIG. 1B, the partition unit 22 is used to separate the first reaction space 2000 and the second reaction space 2001 or to communicate the first reaction space 2000 and the second reaction space 2001 in the reaction chamber 200. Next refer to FIG. 1A, which is a structure diagram showing a partition unit of embodiment. The partition unit 22 includes: a partition plate 220 and a rotator module 221, wherein the rotator module 221 is rotated to move the partition plate 220 in or out of the reaction chamber 200 through the opening 202 so as to control the separation or communication of the first and the second reaction spaces. The rotator module 221 is composed of a motor 2210 and a holder 2211 supporting the partition plate 220. The arc-shaped movement of the partition plate 220 is driven by the motor 2210 with the interfacial support of the holder 2211. The partition plate 220 moves into the reaction chamber 200 through the opening 202 to separate the first 2000 and the second reaction spaces 2001. At the same time, the first 2100 and the second reaction spaces 2101 of the reaction chamber 210 is communicating to each other. Furthermore, in another embodiment as shown in FIG. 1C, the partition unit 22 further includes a shift part 222 providing another dimensional mobility, e.g. in the z-direction, of the partition plate 220. The shift part 222 may provide gastight joint between the partition plate and the sidewall of the reaction chamber, so as to avoid interference and reaction of the process gases in the first and the second reaction spaces.

Refer to FIG. 1A again. The first gas supply unit 23 provides each of the first reaction spaces 2000 and 2100 with a first process gas. The second gas supply unit 24 provides each of the second reaction spaces 2001 and 2101 with a second process gas. The purge gas supply unit 25 provides each of the reaction chambers 200 and 201 with a purge gas to purge the reaction chambers after the film deposition process. The second process gas and the purge gas are introduced into the reaction chambers 200 and 210 through the same gas passages 290 and 291, respectively. It should be noted that the second process gas and the purge gas may be introduced into the reaction chambers 200 and 210 through different respective gas passages. Further, the second process gas and the purge gas are introduced into the reaction chambers 200 and 210 also through the extension parts 27a and 27b respectively, as shown in FIG. 1A, but it is not limited thereby.

Heating carriers 26a and 26b are respectively disposed in the reaction chambers 200 and 210. Each of the heating carriers 26a and 26b can be controlled to move into the first 2000 and 2100 or the second reaction spaces 2001 and 2101. The heating carriers 26a and 26b are used to carry the substrates 90 and 91, respectively, and to increase the temperature of the substrates 90 and 91. The heating and moving mechanisms may be realized by any of the prior-art techniques.

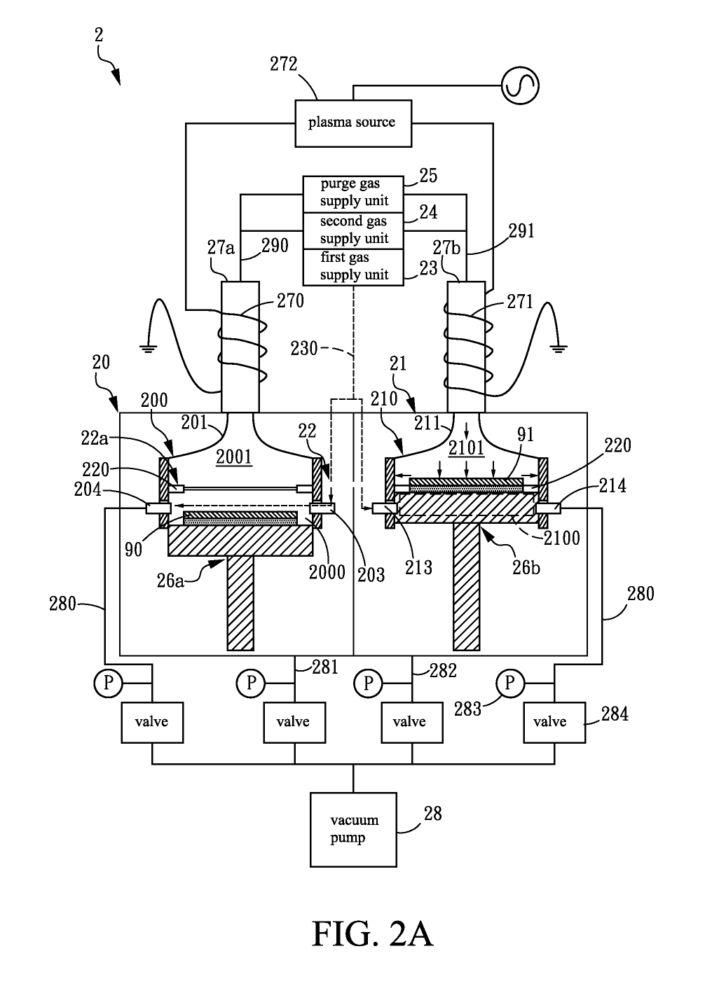

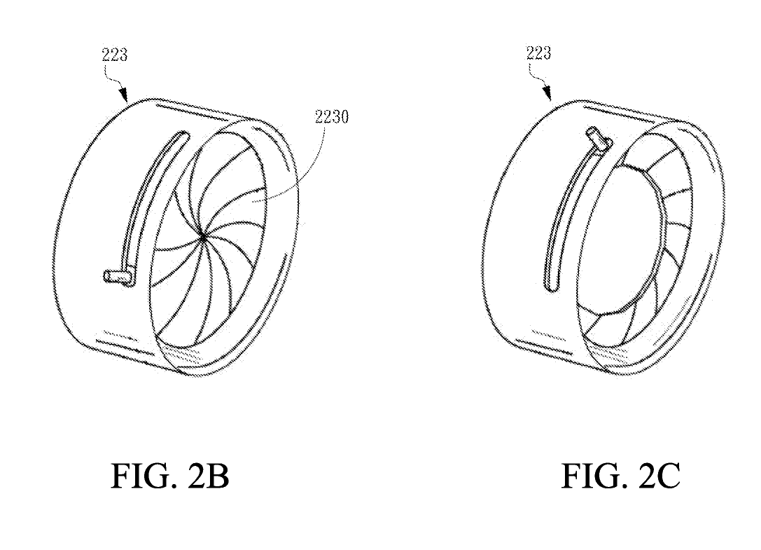

Please refer to FIG. 2A, which is a structure diagram showing another PEALD apparatus according to the second embodiment of the present disclosure. The PEALD apparatus is basically similar to the embodiment shown in FIG. 1A, with a main discrepancy at the structure of the partition unit, which is disposed in the reaction chambers 200 and 201. The partition unit 22a includes a plurality of aperture adjusters 223 as shown in FIGS. 2B and 2C. Each of the aperture adjusters 223 includes a plurality of adjusting blades 2230 to adjust cross-sectional diameters of its aperture, so as to manipulate separation or communication between the first and the second reaction spaces. The operation of the adjusting blades 2230 may be referred to any prior-art technique of aperture adjustment for a camera lens.

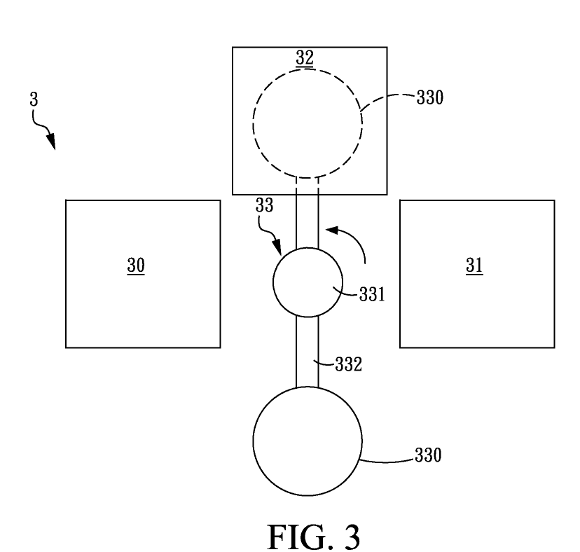

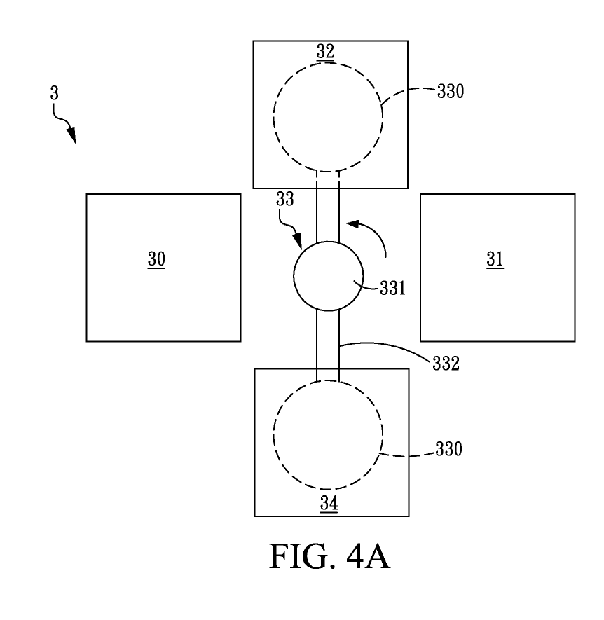

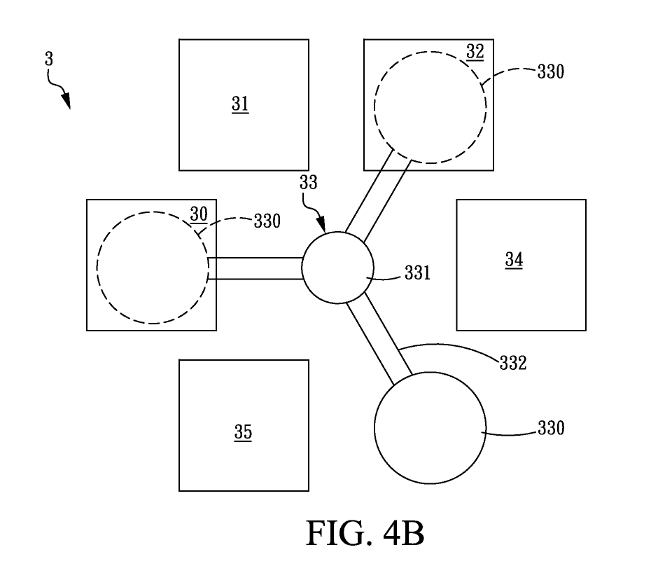

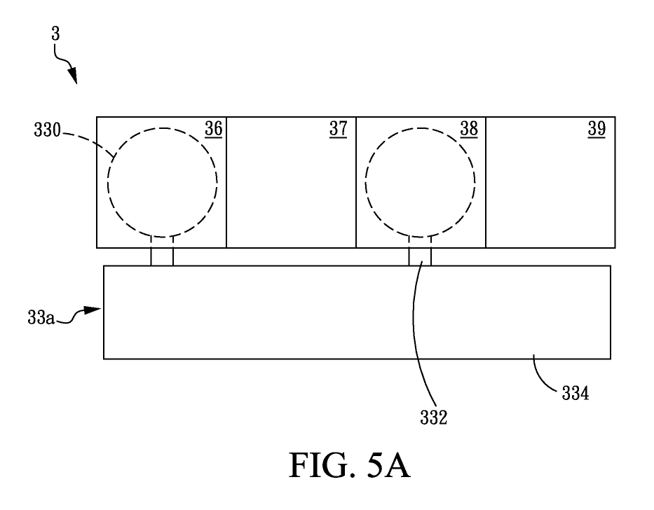

Please refer to FIG. 3, which is a top view schematically showing the PEALD apparatus according to the third embodiment of the present disclosure. The embodiment is particularly used to put emphasis on that the amount of the reactors is not limited to two. In the embodiment, the PEALD apparatus 3 is composed of three reactors 30-32, where the partition unit 33 includes two partition plate 330 and a rotator module 331. A holder 332 is used to support and connect the partition plate 330 to the motor 331. To facilitate alternative operation of the first and the second reaction spaces in each reactor 30-32, the reactors 30 and 31 are correspondingly configured while the reactor 32 is configured on the perpendicular bisector of the reactors 30 and 31. The two holders 332 are disposed with an angle of 180 degrees, whereby when the rotator module 331 rotates by an angle of 90 degrees, the two partition plate 330 are moved accordingly to control the gas provision to the first and the second reaction spaces in each reactor 30-32 for film deposition on the substrates. FIGS. 4A and 4B illustrate top views of other embodiments with another amount of reactors. The layout of the PEALD apparatus with four reactors 30-32 and 34 and a partition unit 33 is schematically shown in FIG. 4A, while the layout of the PEALD apparatus with five reactors 30 to 32 and 34 to 35 and a partition unit 33 is schematically shown in FIG. 4B. As a consequence of the foregoing embodiments, the amount of reactors in the present disclosure is not limited to an odd or even number; the skilled person in the field may configure it in accordance with the practical requirements.

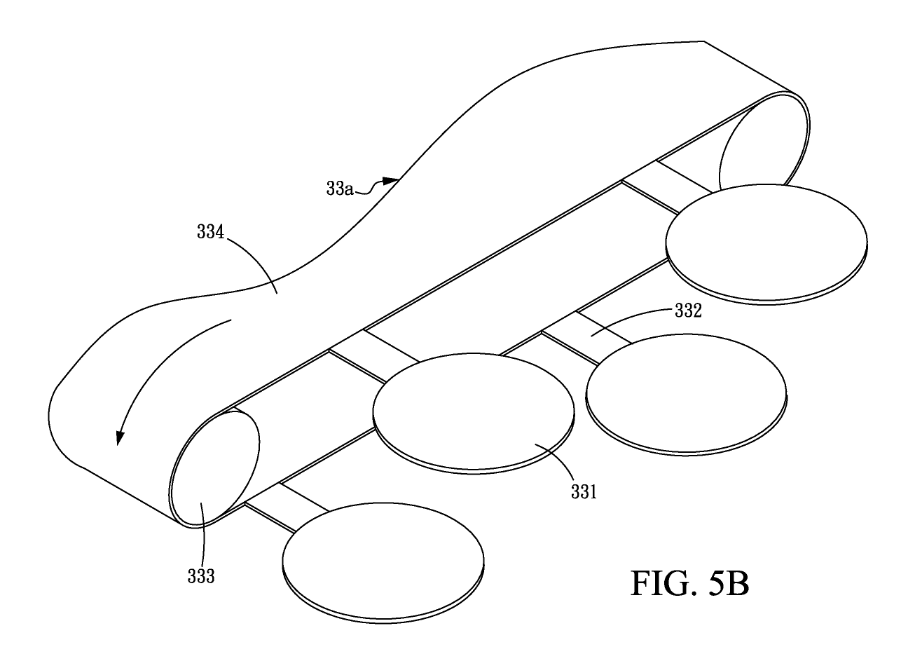

FIG. 5A schematically illustrates another exemplary layout of the PEALD apparatus. In the embodiment, four reactors 36 to 39 are arranged to parallel each other in vertical and align in horizontal. The partition unit 33a with four partition plates 330 corresponding to the PEALD apparatus is schematically illustrated in FIG. 5B. The partition plates 330 are intermittently attached to a transporting carrier 334 with a predetermined interval between the adjacent partition plates 330. The cycled transporting carrier 334 functions with rollers 333 to transport the partition plates 330 linearly and periodically. The partition plate 330, intermittently arranged, are moved accordingly to control the gas provision to the first and the second reaction spaces in each reactor for film deposition on the substrates.

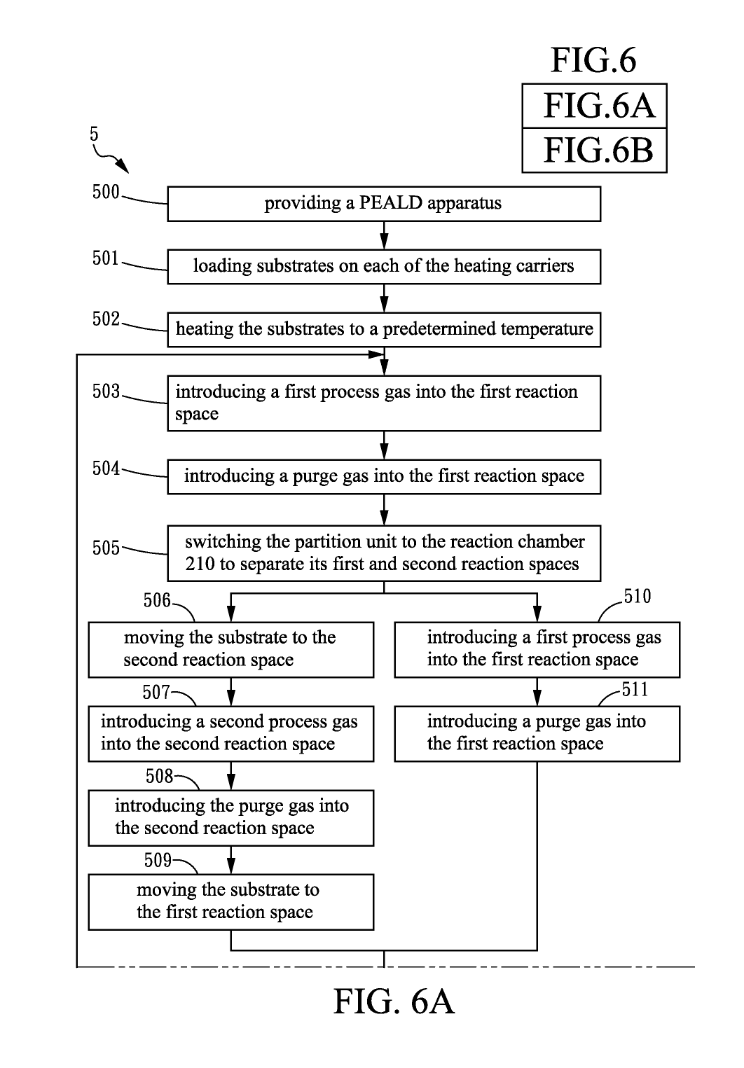

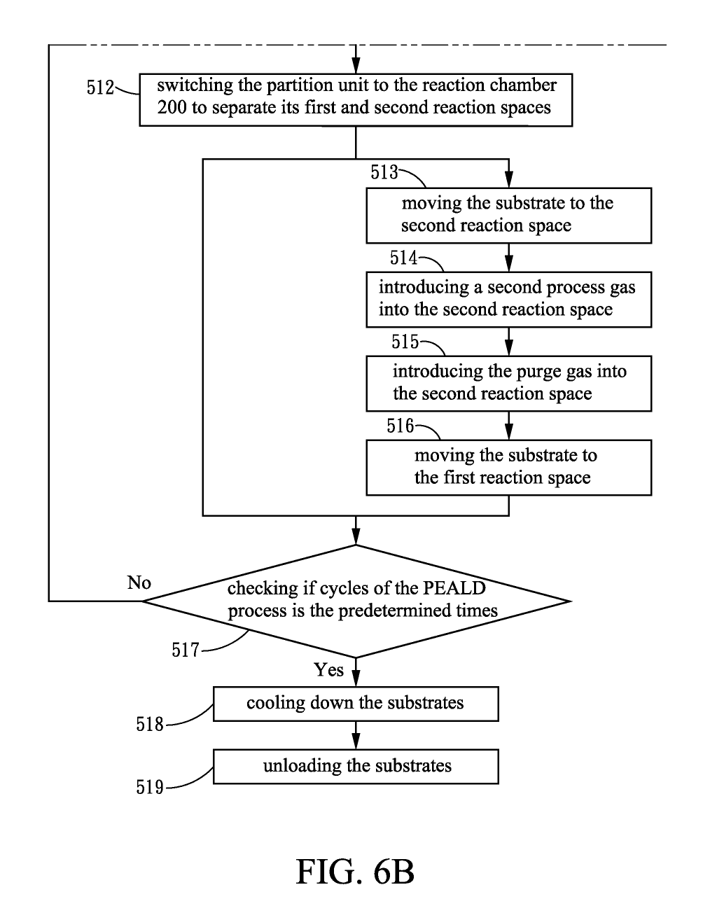

Please refer to FIGS. 6A and 6B, which are flowcharts schematically showing a method of controlling a PEALD apparatus, according to an embodiment of the present disclosure. The method 5 includes the following steps. First in step 500, a PEALD apparatus is provided. The PEALD apparatus may be one of the foregoing embodiments, as shown in FIG. 1A, 2A, 3, 4A, 4B, or 5A. In the embodiment, the PEALD apparatus of FIG. 1A is taken as an example in the following description. Next in step 501, each of the heating carriers 26a and 26b is loaded with a substrate. The loading of the substrates may be implemented by any of the prior arts such as a robotic arm. Then in step 502, the heating carriers 26a and 26b in each reaction chamber 200 and 210 are respectively controlled to heat the substrate 90 and 91 to a predetermined temperature.

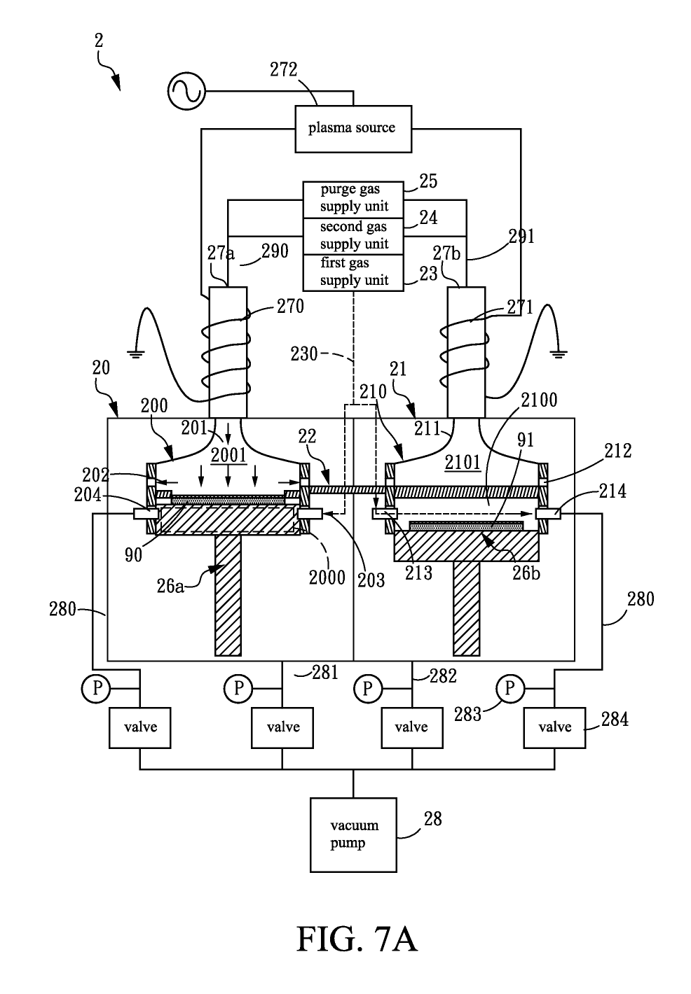

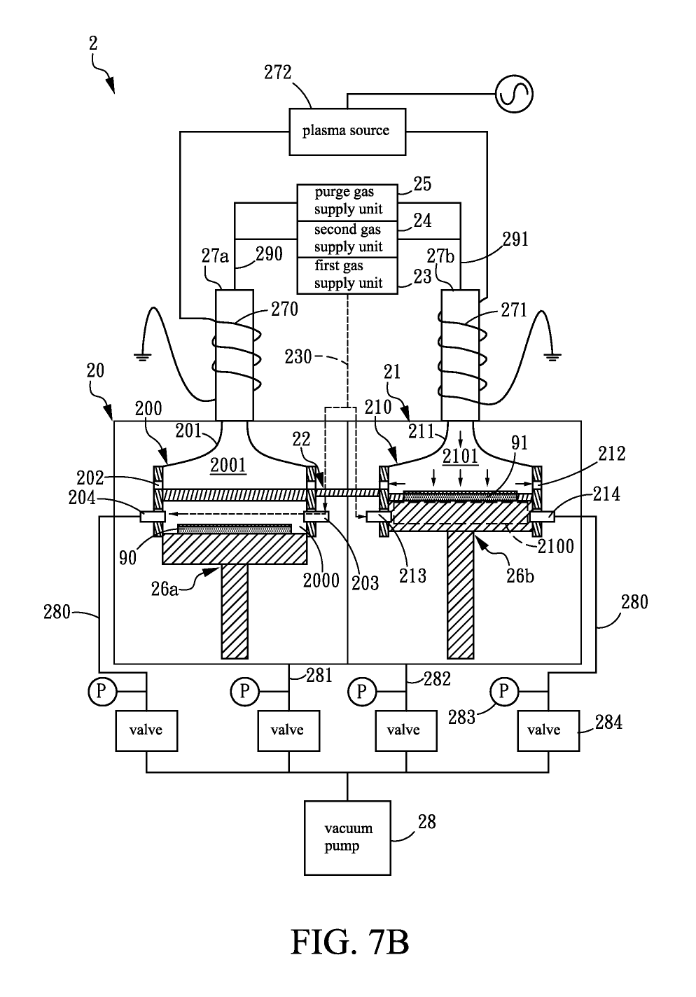

In step 503, a first process gas, as a first precursor, is introduced into the first reaction space 2000 of the reaction chamber 200 from the first gas supply unit 23. Next in step 504, a purge gas is introduced into the first reaction space 2000 of the reaction chamber 200 to purge the reaction space. Next in step 505, the partition unit is switched to the reaction chamber 210 of the other reactor 21, and, hence, the first 2100 and the second 2101 reaction spaces of the reaction chamber 210 is separated. This situation can be schematically illustrated in FIG. 7A. After the step 505, the process is divided into two procedures, steps 506 to 509 and steps 510 to 511, exercised in the two reaction chamber 200 and 210, respectively. Once the steps 506 to 509 and steps 510 to 511 are done, the process goes to step 512 simultaneously. In the reaction chamber 200, the substrate 90 is moved to the second reaction space 2001 of the reaction chamber in step 506. Next in step 507, a second process gas, as a second precursor, is introduced into the first reaction space 2001 of the reaction chamber 200 from the second gas supply unit 24. After the PEALD process is applied to the substrate for a predetermined time, step 504 introduces a purge gas into the second reaction space 2001 of the reaction chamber 200 to purge the reaction space. Next in step 509, the heating carriers 26a is moved down to the corresponding position in the first reaction space 2000.

On the other hand, as the proceeding of steps 506 to 509 in the reaction chamber 200, steps 510 to 511 goes in the reaction chamber 210. In step 510, the first gas or precursor is introduced into the first reaction space 2100 of the reaction chamber 200 from the first gas supply unit 23. Next in step 504, a purge gas is introduced into the first reaction space 2000 of the reaction chamber 200 to purge the reaction space. After the PEALD process is applied to the substrate for a predetermined time, step 511 introduces a purge gas into the second reaction space 2100 of the reaction chamber 210 to purge the reaction space. After steps 509 and 11 are done, in step 512 the partition unit in moved to the reaction chamber 200 to separate the first 2000 and the second 2001 reaction spaces in the reactor 20. This can be schematically illustrated in FIG. 7B.

One cycle of the PEALD process has been applied to the substrates in the reaction chamber 200 as described in the foregoing steps, while it is still not completed in the reaction chamber 210. Next in step 513, in the reaction chamber 210 the substrate 91 is moved to the second reaction space 2101 of the reaction chamber. Next in step 514, the second gas or precursor is introduced into the first reaction space 2101 from the second gas supply unit 24. After the PEALD process is applied to the substrate for a predetermined time, step 515 introduces the purge gas into the second reaction space 2101 of the reaction chamber 210 to purge the reaction space. Next in step 516, the heating carriers 26b is moved down to the corresponding position in the first reaction space 2100. The whole cycle of the method for both the reaction chambers 200 and 210 is composed of steps 503 to 516, then step 517 is to check if cycles of the PEALD process is applied to the substrates for a predetermined times. If the predetermined cycles have been applied, it goes to step 518 to cool down the substrates and then step 519 to unload the processes substrates 90 and 91; otherwise, it may go back to step 503 to proceed steps 503 to 516 again.

With respect to the above description then, it is to be realized that the optimum dimensional relationships for the parts of the disclosure, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present disclosure.

What is claimed is:

1. A plasma enhanced atomic layer deposition apparatus comprising:
a plurality of reaction chambers, each of the reaction chambers having a first reaction space and a second reaction space;
an adjustable partition unit controlled to separate or communicate the first and the second reaction spaces;
a first gas supply unit providing each of the first reaction spaces with a first process gas;
a second gas supply unit providing each of the second reaction spaces with a second process gas;
a purge gas supply unit providing each of the reaction chambers with a purge gas to purge the reaction chambers; and
a plurality of heating carriers respectively disposed in the plurality of reaction chambers, each of the heating carriers controlled to move between the first and second reaction spaces in a reciprocating manner.

2. The plasma enhanced atomic layer deposition apparatus of claim 1, wherein each of the reaction chambers further comprises an extension part connected to the second and the purge gas supply units, wherein a plasma generating coil with a remote plasma source is disposed around the extension part.

3. The plasma enhanced atomic layer deposition apparatus of claim 1, wherein each of the reaction chambers further comprises an opening, and the partition unit further comprises a partition plate and a rotator module, wherein the rotator module is rotated to move the partition plate in or out of the reaction chamber through the opening so as to control separation or communication of the first and the second reaction spaces.

4. The plasma enhanced atomic layer deposition apparatus of claim 1, wherein the partition unit further comprises a plurality of aperture adjusters respectively disposed in the reaction chambers, each of the aperture adjusters comprising a plurality of adjusting blades to control separation or communication of the first and the second reaction spaces.

5. The plasma enhanced atomic layer deposition apparatus of claim 2, wherein the reaction chamber and extension part are connected with a curve structure.

6. The plasma enhanced atomic layer deposition apparatus of claim 1, wherein the first reaction space further comprises:
a first passage connected to the first gas supply unit as a gas inlet; and
a second passage configured as a gas outlet.

7. The plasma enhanced atomic layer deposition apparatus of claim 1, wherein the reaction chambers are arranged to parallel each other in vertical and align in horizontal, and the partition unit comprises a plurality of partition plates intermittently disposed on a transporting carrier with a predetermined interval between the adjacent partition plates.

8. A plasma enhanced atomic layer deposition apparatus comprising:
a first and second reaction chambers, each of the reaction chambers having a first reaction space and a second reaction space;
a partition plate alternatively switched to one of the reaction chambers and characterized by that if the partition plate is switched to the first reaction chamber, the first and the second reaction spaces thereof are separated and the first and the second reaction spaces of the second reaction chamber are communicated; or if the partition plate is switched to the second reaction chamber, the first and the second reaction spaces thereof are separated and the first and the second reaction spaces of the first reaction chamber are communicated;
a first gas supply unit providing each of the first reaction spaces with a first process gas;
a second gas supply unit providing each of the second reaction spaces with a second process gas;
a purge gas supply unit providing each of the reaction chambers with a purge gas to purge the reaction chambers; and
a pair of heating carriers respectively disposed in the plurality of reaction chambers, each of the heating carriers controlled to move between the first and second reaction spaces in a reciprocating manner.

9. The plasma enhanced atomic layer deposition apparatus of claim 8, wherein each of the reaction chambers further comprises an extension part connected to the second and the purge gas supply units, wherein a plasma generating coil with a remote plasma source is disposed around the extension part.

10. The plasma enhanced atomic layer deposition apparatus of claim 9, wherein the reaction chamber and extension part are connected with a curve structure.

11. The plasma enhanced atomic layer deposition apparatus of claim 8, wherein the first reaction space further comprises:
a first passage connected to the first gas supply unit as a gas inlet; and
a second passage configured as a gas outlet.

12. A method for controlling a plasma enhanced atomic layer deposition (PEALD) apparatus comprising the steps of:
providing a plasma enhanced atomic layer deposition apparatus comprising two reaction chambers and a partition unit, each of the reaction chambers having a heating carrier, a first reaction space provided with a first process gas, and a second reaction space provided with a second process gas to proceed a PEALD process, the partition unit configured to separate the first and the second reaction spaces of one of the reaction chambers while to communicate the first and the second reaction spaces of the other reaction chamber;
providing each of the heating carriers with a substrate;
positioning the partition unit into one of the reaction chamber to separate the first and the second reaction spaces thereof, and the other reaction chamber being a communicated one, wherein the substrate in the separated reaction chamber is located in the first reaction space thereof, while the substrate in the communicated reaction chamber is located in the second reaction space thereof;
forming a thin film on each of the substrates by applying the PEALD process in the reaction chambers;
moving the partition unit into the other reaction chamber, wherein the substrate in the separated reaction chamber is located in the first reaction space thereof, while the substrate in the communicated reaction chamber is located in the second reaction space thereof; and
repeating the foregoing steps of forming and moving for a predetermined times.

13. The method of claim 12, wherein the step of forming comprises:
providing the first reaction space of the separated reaction chamber with the first process gas;
applying the PEALD process to the substrate for a predetermined time; and
providing the first reaction space of the separated reaction chamber with a purge gas to purge the reaction chamber.

14. The method of claim 12, wherein the step of forming comprises:
moving the substrate to the second reaction space of the communicated reaction chamber;
providing the second reaction space of the communicated reaction chamber with the second process gas;
applying the PEALD process to the substrate for a predetermined time;
providing the first reaction space of the communicated reaction chamber with a purge gas to purge the reaction chamber; and
moving the substrate to the first reaction space of the communicated reaction chamber.

15. The method of claim 12, further comprising:
heating the substrate to a predetermined temperature.
